(19) United States
(12) Patent Application Publication
(10) Pub. No.: US 2009/0268412 A1
(43) Pub. Date: Oct. 29, 2009

(54) Housing For An Electronic Device

(76) Inventors: Tung-Ping Lee, Hsichih (TW); Yu-Ling Kuo, Hsichih (TW)

Correspondence Address: CURATOLO SIDOTI CO., LPA, 24500 CENTER RIDGE ROAD, SUITE 280, CLEVELAND, OH, 44145, US

(21) Appl. No.: 12/416,458

(22) Filed: Apr. 1, 2009

(30) Foreign Application Priority Data
Apr. 25, 2008 (TW) 097207166

(51) Int. Cl. H05K 7/16

(52) U.S. Cl. 361/726

(57) ABSTRACT

A housing for an electronic device includes a housing body with a front panel and an outer peripheral panel. A cover is coupled to the housing body, is located in front of the front panel, and is formed with an opening. A locking mechanism includes an actuating member disposed in the opening, a transmitting member coupled to the actuating member and disposed on a rear face of the cover, and a rod member disposed on the rear face of the cover. The transmitting member has a catch portion disposed to be retained at the front panel, and an arm portion. The actuating member drives the transmitting member to rotate such that the catch portion is retained at the front panel and the arm portion pushes one end of the rod member to move, thereby enabling the other end of the rod member to be retained at the outer peripheral panel.

### CROSS-REFERENCE TO RELATED APPLICATION

This application claims priority of Taiwanese Application No. 097207166, filed on Apr. 25, 2008.

### BACKGROUND OF THE INVENTION

1. Field of the Invention

The invention relates to a housing for an electronic device, more particularly to a locking mechanism of a housing for an electronic device.

2. Description of the Related Art

As shown in FIGS. 1, 2 and 3, a housing 1 of a conventional electronic device includes a housing body 11, a cover 12 connected pivotally to a front side of the housing body 11, and a lock 13 disposed on the cover 12. The housing body 11 includes a front panel 111 for retaining a hook 131 of the lock 13. The front panel 111 has a curved guide slot 112 for extension of the hook 131 therethrough. When a user inserts a key (not shown) into a key slot 130 in the lock 13 and brings the hook 131 of the lock 13 to rotate in a direction indicated by the arrow VI (see FIG. 3) such that the hook 131 is rotated to a bottom end of the curved guide slot 112 and is retained at a rear face of the front panel 111, the cover 12 is locked to the housing body 11. To release the locking state of the cover 12 with respect to the housing body 11, the key is turned to bring the hook 131 of the lock 13 to rotate in a direction opposite to that of the arrow VI such that the hook 131 is disengaged from the retaining position at the front panel 111, thereby permitting turning of the cover 12 in a direction indicated by the arrow VII (see FIG. 1) for opening the cover 12.

Since the locking between the cover 12 and the housing body 11 is only through the hook 131 of the lock 13, and since the lock 13 is provided on the cover 12 at a position proximate to a bottom end thereof, the locking strength between the cover 12 and the housing body 11 is relatively weak, and part of the cover 12 proximate to a top end thereof and above the lock 13 can be easily pried open or broken, thereby rendering theft of a hard disk (not shown) within the housing body 11 possible.

In addition, U.S. Pat. No. 5,826,922 discloses a locking mechanism for a computer housing, according to which, two catch members can be brought to move simultaneously to control locking and unlocking between a cover and a housing by rotating a knob. Although such a structure provides a stronger locking strength between the cover and the housing, it is relatively complicated.

### SUMMARY OF THE INVENTION

Therefore, an object of the present invention is to provide a housing for an electronic device, which incorporates a simple locking mechanism that can enhance the locking strength between a cover and a housing body to thereby improve security.

The aforesaid object of the present invention and solutions to technical problems associated therewith may be realized using the following technical means. The housing for an electronic device according to the present invention includes a housing body, a cover, and a locking mechanism.

The housing body includes a front panel and an outer peripheral panel disposed at one of outer peripheral sides of the front panel. The cover is coupled to the housing body and is located in front of the front panel. The cover is formed with an opening and has a rear face. The locking mechanism includes an actuating member disposed in the opening, a transmitting member coupled to the actuating member and disposed on the rear face of the cover, and a rod member disposed on the rear face of the cover. The transmitting member has a catch portion disposed to be retained at the front panel, and an arm portion disposed opposite to the catch portion. The actuating member is disposed to drive the transmitting member to rotate such that the catch portion is retained at the front panel and such that the arm portion pushes one end of the rod member to move so as to enable the other end of the rod member to be retained at the outer peripheral panel.

The object of this invention and the solutions to the technical problems may be further realized using the following technical means.

In the housing for an electronic device according to the invention, the outer peripheral panel is substantially perpendicular to the front panel.

In the housing for an electronic device according to the invention, the outer peripheral panel is spaced apart from and is disposed above the front panel. The outer peripheral panel has an inner panel face, and a protrusion projecting from the inner panel face for retaining the other end of the rod member. The front panel has a curved guide slot for extension of the catch portion therethrough. The catch portion is in the form of a hook and is movable along the curved guide slot when rotated so as to be retained at the front panel.

In the housing for an electronic device according to the invention, the cover further includes a first positioning member disposed on the rear face proximate to a top end thereof. The first positioning member has a through hole for extension of the rod member therethrough. The rod member has an abutting portion disposed below the first positioning member. The locking mechanism further includes a resilient member that is sleeved on the rod member, and that abuts against and that is interposed between the first positioning member and the abutting portion. The resilient member is disposed to provide the rod member with a restoring force so as to enable the rod member to separate from the outer peripheral panel.

In the housing for an electronic device according to the invention, the rod member has a generally slanting first rod portion, a second rod portion extending upwardly from one end of the first rod portion, and a third rod portion extending downwardly from the other end of the first rod portion. The cover further includes a limiting member disposed below the first rod portion for abutment by the first rod portion.

In the housing for an electronic device according to the invention, the cover further includes a second positioning member and a plurality of stop portions disposed respectively on the rear face thereof. The second positioning member is disposed below the first positioning member, and has a fastening groove defined by a generally C-shaped wall. The abutting portion is formed on the second rod portion. The second rod portion extends through the through hole and is clamped by the generally C-shaped wall of the fastening groove. The second rod portion is for engaging the protrusion. Each of the stop portions abuts against one side of the second rod portion to position the second rod portion in the fastening groove.

In the housing for an electronic device according to the invention, the second rod portion has a front side retained at the protrusion. The first positioning member further has a contact portion for abutting against a rear side of the second rod portion.

In the housing for an electronic device according to the invention, the cover further includes a third positioning member disposed on the rear face thereof to be contacted by the arm portion. The third positioning member has a slide slot for extension of the third rod portion therethrough.

In the housing for an electronic device according to the invention, the locking mechanism having a simple structure can be simultaneously locked onto the housing body in two directions to enhance the locking strength between the cover and the housing body and improve security.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view of a housing for a conventional electronic device;

FIG. 2 is a fragmentary enlarged view of the housing for the conventional electronic device;

FIG. 3 is a fragmentary enlarged view of the housing for the conventional electronic device, showing a hook retained at a front panel;

FIG. 4 is a perspective view of a preferred embodiment of a housing for an electronic device according to the present invention when viewed from the front;

FIG. 5 is a perspective view of the preferred embodiment, illustrating a cover in an open state with respect to a housing body;

FIG. 6 is a fragmentary perspective view of the preferred embodiment when viewed from the rear, illustrating the cover in an unlocking state with respect to a front panel and an outer peripheral panel of the housing body;

FIG. 7 is a fragmentary exploded perspective view of the preferred embodiment when viewed from the rear;

FIG. 8 is a rear view of the cover of the preferred embodiment;

FIG. 9 is a schematic bottom view of the preferred embodiment, illustrating second and third rod portions of a rod member extending through a fastening groove in a second positioning member and a slide slot in a third positioning member;

FIG. 10 is a side view of the rod member of the preferred embodiment;

FIG. 11 is a fragmentary perspective view of the preferred embodiment when viewed from the rear, illustrating the cover in a locking state with respect to the front panel and the outer peripheral panel of the housing body;

FIG. 12 is another rear view of the cover of the preferred embodiment;

FIG. 13 is a partly sectioned, schematic side view of a part of the preferred embodiment, illustrating that the second rod portion of the rod member has a front side retained at a protrusion, and a rear side abutting against a contact portion; and

FIG. 14 is a partly sectioned, schematic view of a modified form of the preferred embodiment, showing the rod member as an uprightly extending rod member.

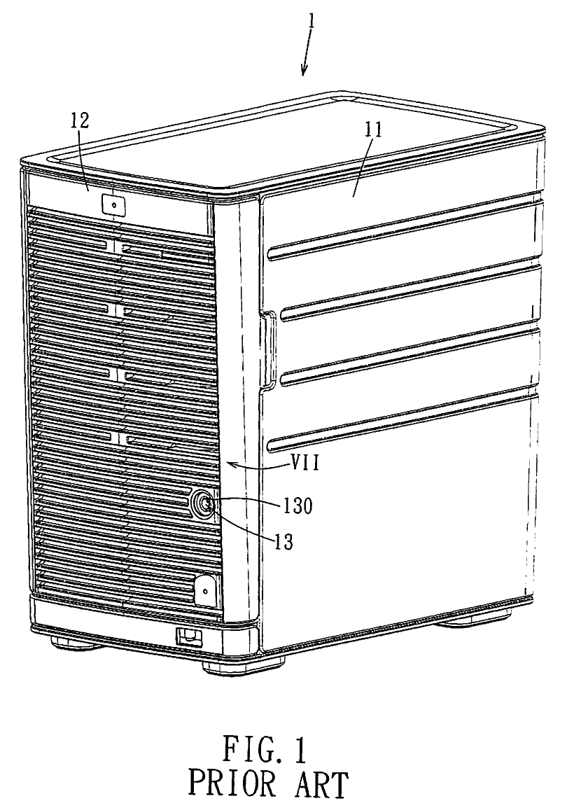

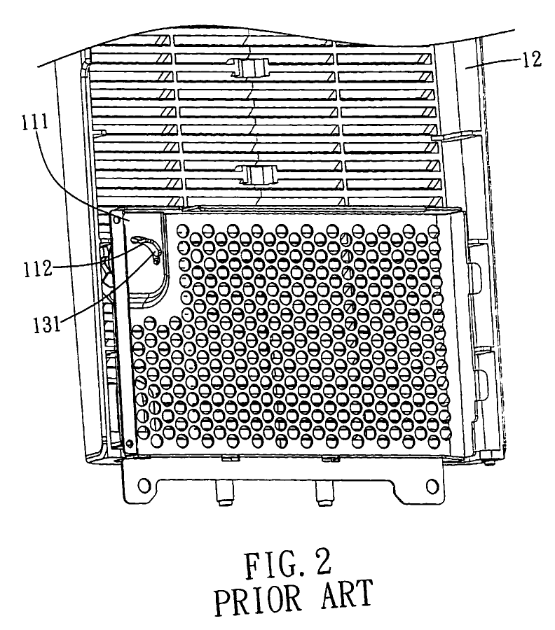

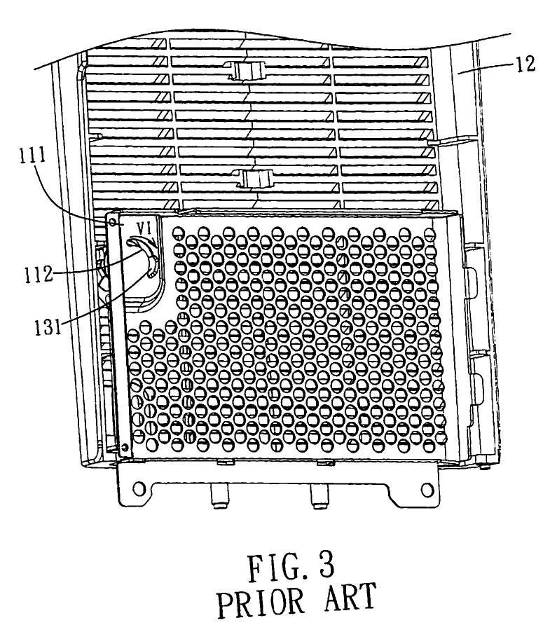

### DETAILED DESCRIPTION OF THE PREFERRED EMBODIMENT

Through a description of the preferred embodiment, the technical means employed by the present invention to achieve the intended object, and the advantageous effects contemplated thereby, can be better understood and appreciated. However, it is noted that the accompanying drawings are for illustrative purpose and reference only, and are not intended to limit the scope of the present invention.

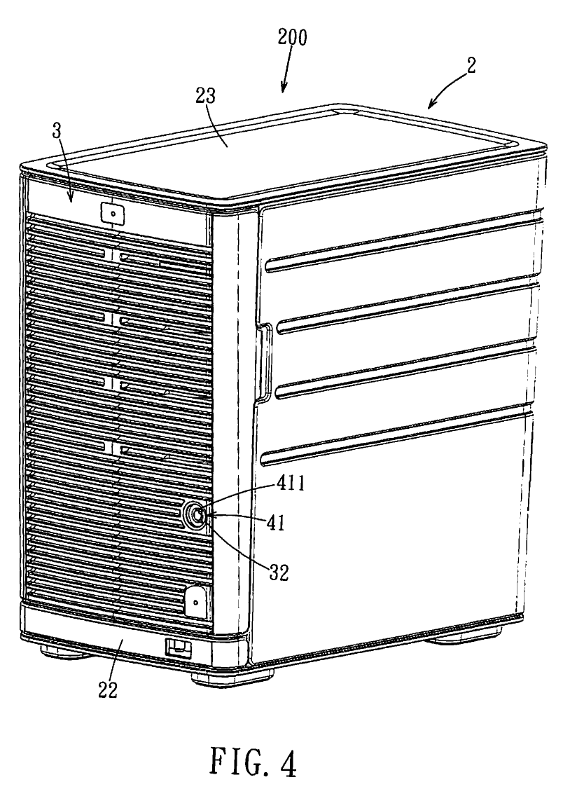

FIGS. 4, 5, and 6 show the preferred embodiment of a housing 200 of an electronic device according to the present invention. The electronic device may be a server or a computer device. The housing 200 of the electronic device includes a housing body 2, a cover 3, and a locking mechanism 4.

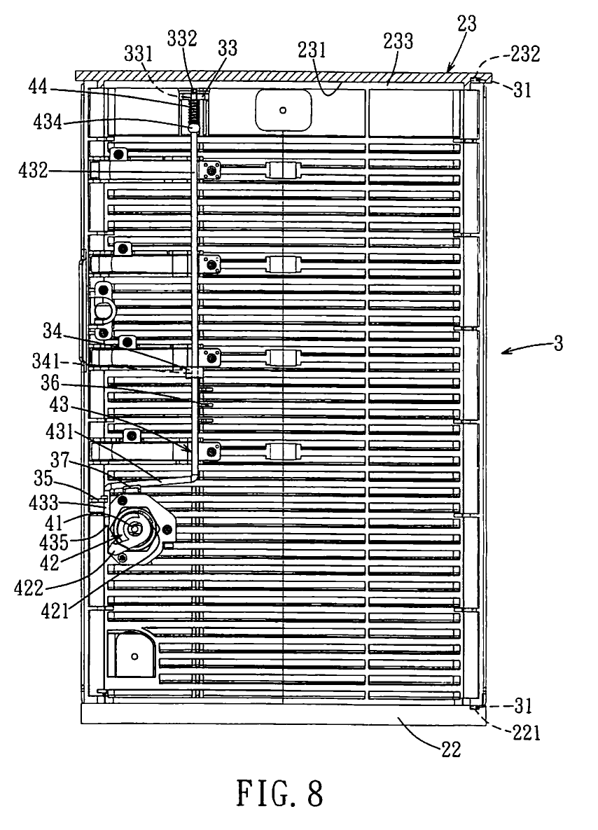

The housing body 2 includes a plurality of drawable hard disk cases 20 disposed therein for receiving hard disks (not shown), a front panel 21 disposed below the hard disk cases 20, a bottom frame 22 disposed at a bottom side of the front panel 21, and an outer peripheral panel 23 disposed above the hard disk cases 20. The front panel 21 has a curved guide slot 211 proximate to a corner of a top end thereof. The bottom frame 22 has a pivot hole 221 (see FIG. 8) formed in a top face thereof. The outer peripheral panel 23 is a cover plate spaced apart from and disposed above the front panel 21. The outer peripheral panel 23 extends along a front-rear direction that is perpendicular to a top-down direction of extension of the front panel 21. The outer peripheral panel 23 has an inner panel face 231, a pivot hole 232 (see FIG. 8) formed in the inner panel face 231, and a protrusion 233 projecting from the inner panel face 231. The pivot hole 221 in the bottom frame 22 corresponds in position to the pivot hole 232 in the outer peripheral panel 23 for pivotal connection with the cover 3. In this embodiment, the protrusion 233 is a loop protrusion.

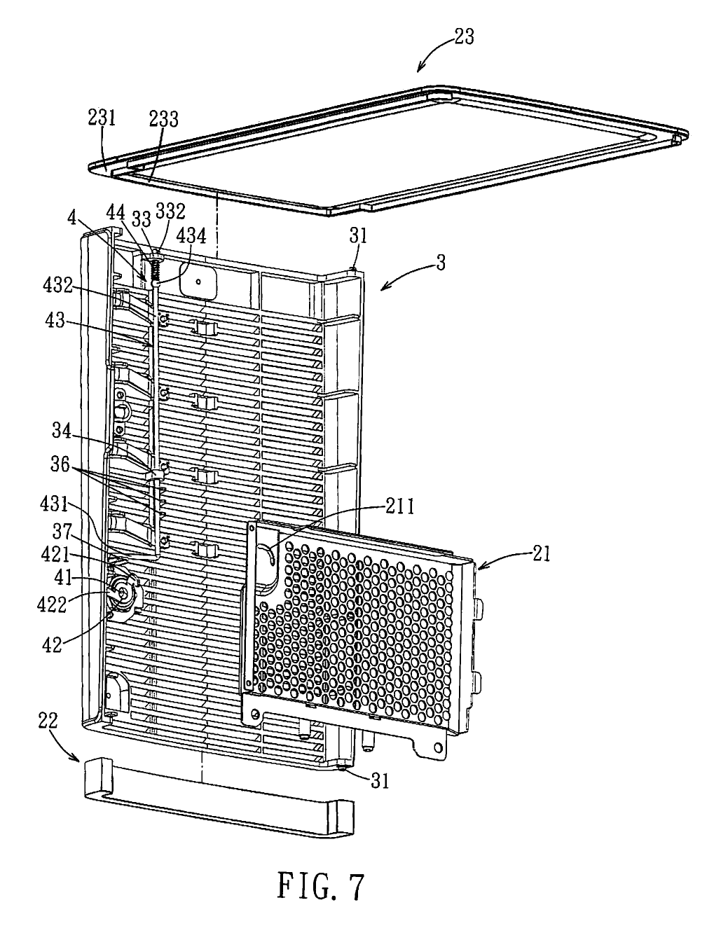

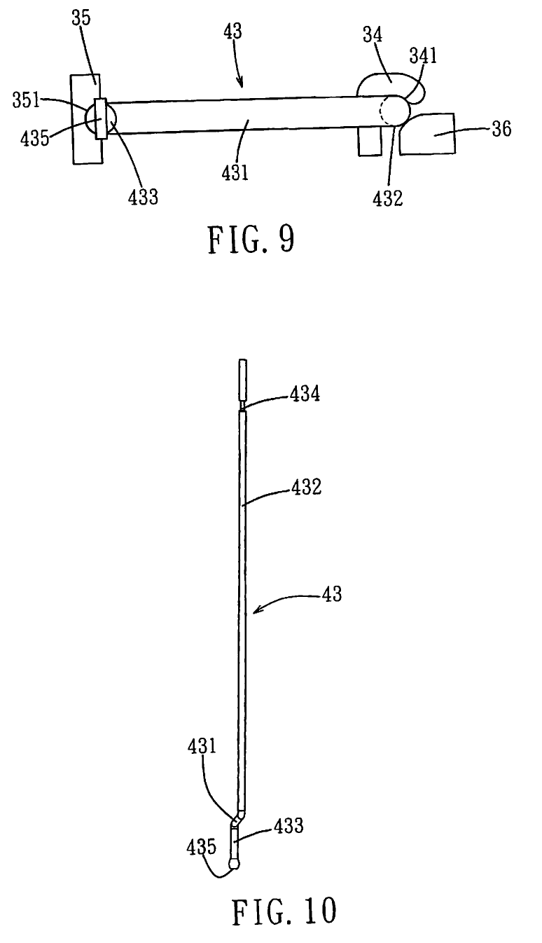

With reference to FIGS. 7 and 8, the part to the right of the cover 3 depicted in the rear view of FIG. 7 is referred to as the right side, and the part to the left of the cover 3 is referred to as the left side. The cover 3 includes two pivot posts 31 disposed on the right side and connected pivotally and respectively to the pivot holes 221, 232. The cover 3 is formed with an opening 32 (see FIG. 4) provided proximate to the left side, and has a first positioning member 33, a second positioning member 34, a third positioning member 35, a plurality of stop portions 36, and a limiting member 37 disposed on a rear face thereof. The first positioning member 33 extends rearwardly from the rear face of the cover 3 and is in the form of a horizontally extending tab. The first positioning member 33 has a through hole 331, and a contact portion 332 projecting from a top face thereof and disposed behind the through hole 331. The second positioning member 34 is in the form of a hook and is disposed below the first positioning member 33. The second positioning member 34 has a fastening groove 341 defined by a generally C-shaped wall (see FIG. 9). The stop portions 36 are spacedly disposed below the second positioning member 34. The third positioning member 35 is disposed proximate to the left side of the cover 3, and has a slide slot 351 (see FIG. 9) that opens to the right. The limiting member 37 is disposed on the right side of the third positioning member 35.

The locking mechanism 4 includes an actuating member 41, a transmitting member 42, a rod member 43, and a resilient member 44. The actuating member 41 is mounted in the opening 32 in the cover 3, and has a key slot 411 (see FIG. 4) disposed in a front side of the cover 3 for receiving a key (not shown). The transmitting member 42 is coupled to the actuating member 41 and is disposed on the rear face of the cover 3. The transmitting member 42 has a catch portion 421 in the form of a hook and disposed to extend through the curved guide slot 211, and an arm portion 422 disposed opposite to the catch portion 421. The actuating member 41 drives the transmitting member 42 to rotate, so that the catch portion 421 is movable along the curved guide slot 211 to engage the front panel 21 when the transmitting member 42 is rotated.

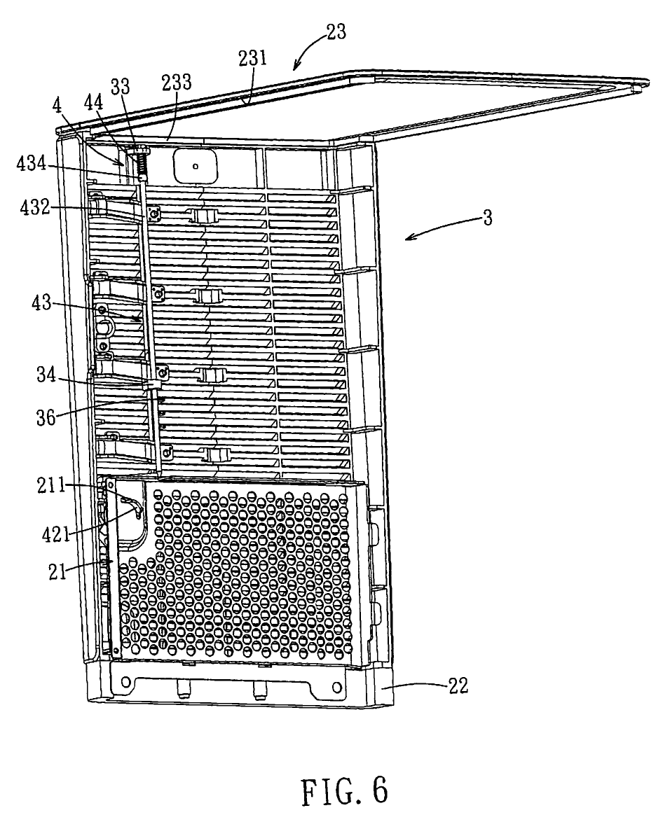

With reference to FIGS. 6, 8 and 9, in which FIG. 9 is a schematic bottom view, the coupling relationship of the rod member 43 with the second and third positioning members 34, 35, and the stop portions 36 will now be described. The rod member 43 is formed from a metal material, and has a generally slanting first rod portion 431, a second rod portion 432 extending upwardly from a right end of the first rod portion 431, a third rod portion 433 extending downwardly from a left end of the first rod portion 431, and an abutting portion 434 formed on and adjacent to a top end of the second rod portion 432. The second rod portion 432 extends through the through hole 331 in the first positioning member 33 and is clamped by the generally C-shaped wall of the fastening groove 341 in the second positioning member 34. The third rod portion 433 extends through the slide slot 351 in the third positioning member 35. The rod member 43 is thus vertically and movably mounted to the rear face of the cover 3. Each stop portion 36 abuts against the right side of the second rod portion 432, so that the second and third rod portions 432, 433 can be respectively and stably positioned in the fastening groove 341 and the slide slot 351, thereby preventing removal of the rod member 43 from the fastening groove 341 and the slide slot 351 due to external forces. In this embodiment, the rod member 43 may be formed from plastic or other materials, although metal material provides better strength.

The abutting portion 434 of the rod member 43 is a generally circular plate for abutment by the resilient member 44. The resilient member 44 is a compression spring that is sleeved on the second rod portion 432 and that abuts against and that is interposed between the first positioning member 33 and the abutting portion 434 for providing the rod member 43 with a resilient force required when restoring the same. In addition, a bottom end 435 of the third rod portion 433 is generally elongated in a front to rear direction (as shown in FIG. 10), and is disposed above the arm portion 422 of the transmitting member 42 for contacting the arm portion 422 of the transmitting member 42. The arm portion 422 has an elongated top end. The top end of the arm portion 422 intersects the bottom end 435 of the third rod portion 433 when the arm portion 422 is rotated to a certain angular position. Thus, when the actuating member 41 drives the transmitting member 42 to rotate, the arm portion 422 of the transmitting member 42 can be positively brought into contact with the bottom end 435 of the third rod portion 433 so as to push the bottom end 435 of the third rod portion 433 and to bring the rod member 43 to move upwardly, thereby enabling the second rod portion 432 to be retained at the protrusion 233 of the outer peripheral panel 23.

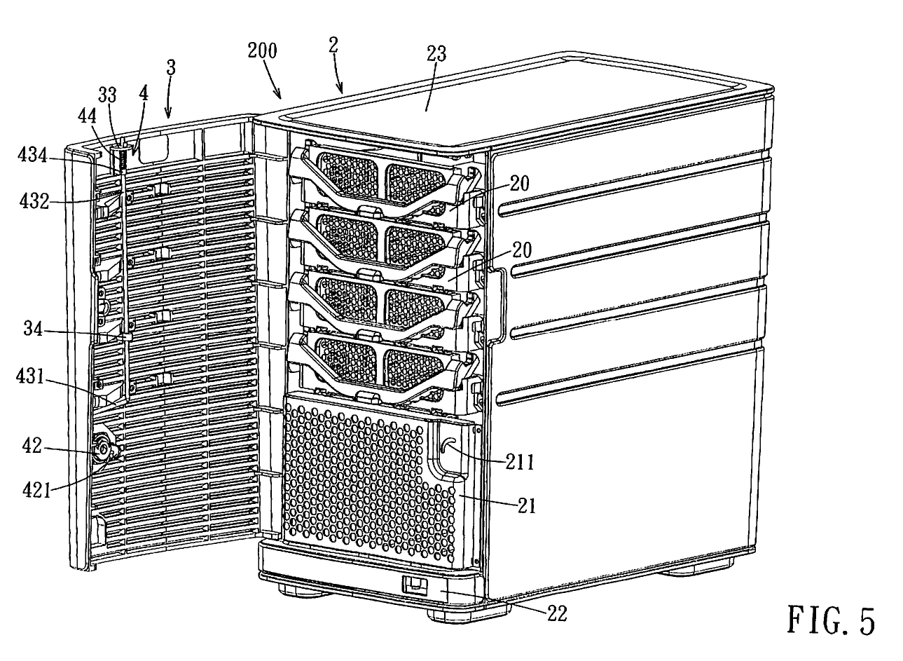

When the catch portion 421 of the transmitting member 42 extends through the curved guide slot 211 and is proximate to a top end of the curved guide slot 211, the arm portion 422 of the transmitting member 42 does not contact the third rod portion 433 of the rod member 43. Moreover, due to the resilient action of the resilient member 44, the first rod portion 431 of the rod member 43 can abut against the limiting member 37, while the second rod portion 432 of the rod member 43 does not engage the protrusion 233 of the outer peripheral panel 23. At this time, the cover 3 is in an unlocking state with respect to the housing body 2, and the user may rotate the cover 3 relative to the housing body 2 about the pivotal connection between the cover 3 and the housing body 2 to thereby open the cover 3 (as shown in FIG. 5).

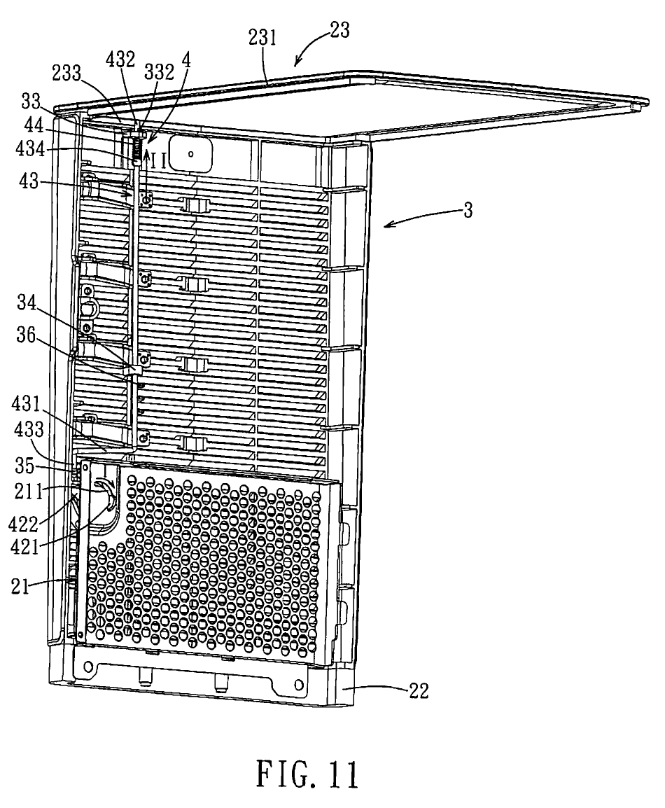

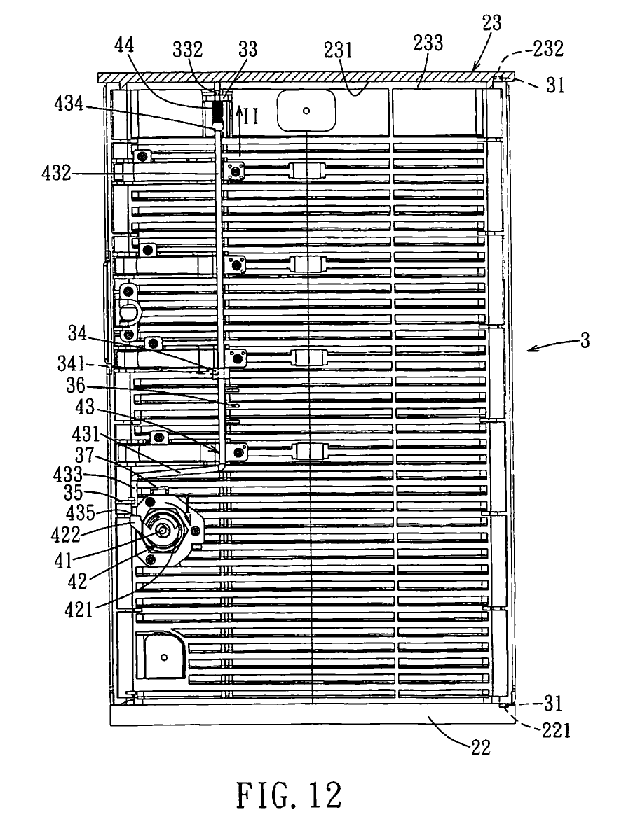

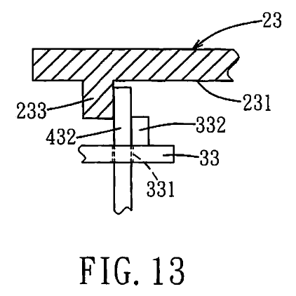

Referring to FIGS. 11, 12 and 13, in which FIG. 13 is a schematic side view, the engagement relationship between the second rod portion 432 of the rod member 43 and the protrusion 233 of the outer peripheral panel 23 is illustrated. After the user has inserted the key into the key slot 411 (see FIG. 4) in the actuating member 41, the actuating member 41 is driven in a direction indicated by the arrow I (see FIG. 11) so as to bring the transmitting member 42 to rotate. When the catch portion 421 of the transmitting member 42 is rotated to a bottom end of the curved guide slot 211 and cannot be rotated further, the catch portion 421 will be retained at the rear face of the front panel 21. At the same time, the arm portion 422 of the transmitting member 42 will push the bottom end 435 of the third rod portion 433 to bring the rod member 43 to move upwardly in a direction indicated by the arrow II (see FIG. 11), with the abutting portion 434 compressing the resilient member 44, so that a front side of the second rod portion 432 that is proximate to the top end thereof is retained at a rear side or the protrusion 233 of the outer peripheral panel 23. At this time, the cover 3 is in a locking state with respect to the housing body 2, and the first rod portion 431 of the rod member 43 is separated from the limiting member 37 and is located above the limiting member 37. By means of the arrangement of the transmitting member 42 and the rod member 43 of the locking mechanism 4, the actuating member 41 can drive the catch portion 421 of the transmitting member 42 to rotate so as to be retained at the front panel 21, while bringing the rod member 43 to displace upward at the same time so as to enable the second rod portion 432 to be retained at the protrusion 233 of the outer peripheral panel 23. Therefore, the locking mechanism 4 may be simultaneously locked onto the housing body 2 in two directions, which not only enhances the locking strength between the cover 3 and the housing body 2, the part of the cover 3 that is proximate to the top end thereof and that is above the actuating member 41 can be protected against prying and damage, thereby improving security. In addition, the locking mechanism 4 is relatively simple in structure, thereby reducing design and manufacturing costs.

Furthermore, when a force is applied to the cover 3 in an attempt to pry open the cover 3, the contact portion 332 of the first positioning member 33 will abut against a rear side of the second rod portion 432 to thereby increase the area of contact between the first positioning member 33 and the second rod portion 432, so that the second rod portion 432 can, upon being subjected to a counter force from the protrusion 233, transmit the force evenly to the first positioning member 33. In addition, in this embodiment, although the protrusion 233 has a loop structure, it is apparent from the foregoing description that the protrusion 233 may also have a block structure. The block structure is required to project from the inner panel face 231 of the outer peripheral panel 23 and to be located at the front side of the second rod portion 432 in order to achieve the same effect of retaining the second rod portion 432. The protrusion 233 is therefore not limited to the loop structure disclosed in the preferred embodiment.

Referring to FIGS. 6 and 8, when the user rotates the transmitting member 42 in a direction opposite to that indicated by the arrow I (see FIG. 11), and when the catch portion 421 of the transmitting member 42 is rotated to a point near the top end of the curved guide slot 211 to be thereby disengaged from the front panel 21, the arm portion 422 of the transmitting member 42 will rotate downwardly simultaneously to separate from the third rod portion 433. At this time, the rod member 43 moves downwardly to a position shown in FIG. 8 due to the restoring force of the resilient member 44, so that the second rod portion 432 of the rod member 43 is separated from the protrusion 233 of the outer peripheral panel 23. The cover 3 can thus be returned to the unlocking state with respect to the housing body 2.

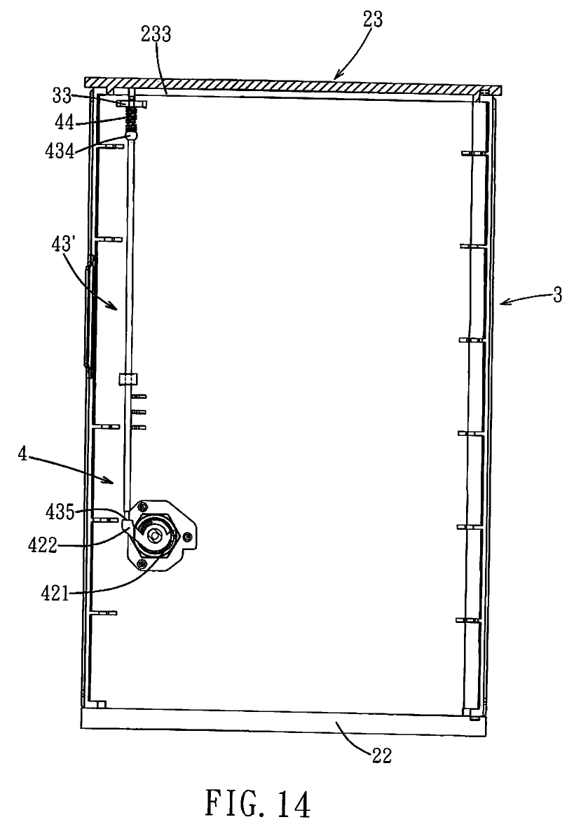

It is particularly noted that the rod member 43′ may also be configured to extend uprightly, as shown in FIG. 14, depending on the design of the housing body 2 and the cover 3, and that the locking mechanism 4 may dispense with the catch portion 421 of the transmitting member 42, so as to permit locking between the housing body 2 and the cover 3 in a single direction. Furthermore, the outer peripheral panel 23, against which the rod member 43, 43′ can be retained, is not limited to the position above the front panel 21, and may be disposed at one of the outer peripheral sides of the front panel 21. The arrangement of the rod member 43, 43′ may be designed in accordance with the position of the outer peripheral panel 23, such that the locking mechanism 4 may still be locked at the front panel 21 and the outer peripheral panel 23.

In sum, in the housing 200 for an electronic device according to the present invention, the locking mechanism 4 having a simple structure can be simultaneously locked onto the housing body 2 in two directions to enhance the locking strength between the cover 3 and the housing body 2 and to improve security.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements. In addition, it should be appreciated that any of the embodiments of this invention or any of the claims as appended hereto does not necessarily have to achieve all of the objects, advantages or features disclosed herein. Moreover, the title of the invention and the abstract of the disclosure are provided herein to allow a searcher to quickly ascertain the subject matter of the technical disclosure of any patent issued on this application, and should not be relied upon to limit the scope of protection sought for this invention.

What is claimed is:

1. A housing for an electronic device, comprising:
a housing body including a front panel and an outer peripheral panel disposed at one of outer peripheral sides of said front panel;
a cover coupled to said housing body and located in front of said front panel, said cover being formed with an opening and having a rear face; and
a locking mechanism including an actuating member disposed in said opening, a transmitting member coupled to said actuating member and disposed on said rear face of said cover, and a rod member disposed on said rear face of said cover, said transmitting member having a catch portion disposed to be retained at said front panel, and an arm portion disposed opposite to said catch portion, said actuating member being disposed to drive said transmitting member to rotate such that said catch portion is retained at said front panel and such that said arm portion pushes one end of said rod member to move so as to enable the other end of said rod member to be retained at said outer peripheral panel.

2. The housing for an electronic device according to claim 1, wherein said outer peripheral panel has an inner panel face, and a protrusion projecting from said inner panel face for retaining said other end of said rod member.

3. The housing for an electronic device according to claim 1, wherein said front panel has a curved guide slot for extension of said catch portion therethrough, said catch portion having a form of a hook and being movable along said curved guide slot when rotated so as to be retained at said front panel.

4. The housing for an electronic device according to claim 1, wherein said locking mechanism further includes a resilient member for providing said rod member with a restoring force so as to enable said rod member to separate from said outer peripheral panel.

5. The housing for an electronic device according to claim 1, wherein said outer peripheral panel is substantially perpendicular to said front panel.

6. The housing for an electronic device according to claim 1, wherein said cover further includes a first positioning member disposed on said rear face thereof, said first positioning member having a through hole for extension of said rod member therethrough.

7. The housing for an electronic device according to claim 6, wherein said cover further includes a second positioning member disposed on said rear face thereof, said second positioning member having a fastening groove defined by a generally C-shaped wall for clamping said rod member.

8. The housing for an electronic device according to claim 2, wherein said front panel has a curved guide slot for extension of said catch portion therethrough, said catch portion having a form of a hook and being movable along said curved guide slot when rotated so as to be retained at said front panel.

9. The housing for an electronic device according to claim 8, wherein said locking mechanism further includes a resilient member for providing said rod member with a restoring force so as to enable said rod member to separate from said outer peripheral panel.

10. The housing for an electronic device according to claim 9, wherein said outer peripheral panel is substantially perpendicular to said front panel, and is spaced apart from and is disposed above said front panel.

11. The housing for an electronic device according to claim 10, wherein said cover further includes a first positioning member disposed on said rear face thereof, said first positioning member having a through hole for extension of said rod member therethrough.

12. The housing for an electronic device according to claim 11, wherein said cover further includes a second positioning member disposed on said rear face thereof, said second positioning member having a fastening groove defined by a generally C-shaped wall for clamping said rod member.

13. The housing for an electronic device according to claim 5, wherein said outer peripheral panel is spaced apart from and is disposed above said front panel, said outer peripheral panel having an inner panel face, and a protrusion projecting from said inner panel face for retaining said other end of said rod member, said front panel having a curved guide slot for extension of said catch portion therethrough, said catch portion having a form of a hook and being movable along said curved guide slot when rotated so as to be retained at said front panel.

14. The housing for an electronic device according to claim 13, wherein said cover further includes a first positioning member disposed on said rear face proximate to a top end thereof, said first positioning member having a through hole for extension of said rod member therethrough, said rod member having an abutting portion disposed below said first positioning member, said locking mechanism further including a resilient member that is sleeved on said rod member, and that abuts against and that is interposed between said first positioning member and said abutting portion, said resilient member being disposed to provide said rod member with a restoring force so as to enable said rod member to separate from said outer peripheral panel.

15. The housing for an electronic device according to claim 14, wherein said rod member has a generally slanting first rod portion, a second rod portion extending upwardly from one end of said first rod portion, and a third rod portion extending downwardly from the other end of said first rod portion, said second rod portion being disposed to be retained at said protrusion.

16. The housing for an electronic device according to claim 15, wherein said cover further includes a limiting member disposed below said first rod portion for abutment by said first rod portion.

17. The housing for an electronic device according to claim 15, wherein said cover further includes a second positioning member disposed on said rear face thereof, said second positioning member being disposed below said first positioning member and having a fastening groove defined by a generally C-shaped wall, said abutting portion being formed on said second rod portion, said second rod portion extending through said through hole and being clamped by said generally C-shaped wall of said fastening groove.

18. The housing for an electronic device according to claim 17, wherein said cover further includes a plurality of stop portions disposed on said rear face thereof, each of said stop portions abutting against one side of said second rod portion to position said second rod portion in said fastening groove.

19. The housing for an electronic device according to claim 17, wherein said second rod portion has a front side retained at said protrusion, said first positioning member further having a contact portion for abutting against a rear side of said second rod portion.

20. The housing for an electronic device according to claim 19, wherein said cover further includes a third positioning member disposed on said rear face thereof to be contacted by said arm portion, said third positioning member having a slide slot for extension of said third rod portion therethrough.

21. A housing for an electronic device, comprising:
a housing body including an outer peripheral panel;
a cover disposed at one side of said outer peripheral panel, said cover being formed with an opening and having a rear face; and
a locking mechanism including an actuating member disposed in said opening, a transmitting member coupled to said actuating member and disposed on said rear face of said cover, and a rod member disposed on said rear face of said cover, said transmitting member having an arm portion, said actuating member being disposed to drive said transmitting member to rotate such that said arm portion pushes one end of said rod member to move so as to enable the other end of said rod member to be retained at said outer peripheral panel.

22. The housing for an electronic device according to claim 21, wherein said housing body further includes a front panel disposed at said one side of said outer peripheral panel, said cover being coupled to said housing body and being located in front of said front panel, said transmitting member having a catch portion disposed opposite to said arm portion and to be retained at said front panel, said catch portion being retained at said front panel when said actuating member drives said transmitting member to rotate.
